(19) United States
(12) Patent Application Publication
(10) Pub. No.: US 2021/0087914 A1
(43) Pub. Date: Mar. 25, 2021

(54) ENERGY PRODUCTION, USE AND RECOVERY METHODS

(71) Applicant: Julian Nalley, JR., Sugar Land, TX (US)

(72) Inventor: Julian Nalley, JR., Sugar Land, TX (US)

(21) Appl. No.: 16/580,787

(22) Filed: Sep. 24, 2019

(51) Int. Cl. E21B 43/243; H05K 7/20

(52) U.S. Cl. CPC E21B 43/243; E21B 41/0085; H05K 7/20318

(57) ABSTRACT

A method providing for a first industrial process that produces heat, extracting a waste heat from the first industrial process, providing the extracted waste heat from the first industrial process to a second process, conducting at least one cooling process.

### CROSS-REFERENCE TO RELATED APPLICATIONS

None.

### FIELD OF THE DISCLOSURE

Aspects of the disclosure relate to production of energy and recovery of energy. More specifically, aspects of the disclosure relate to efficient production, use and recovery of energy by energy intensive applications in remote locations.

### BACKGROUND

Use of energy is becoming an increasingly important aspect of society. Ramifications of the use of energy has also become an important topic of conversation and business as society wishes to more efficiently use available energy streams.

One such energy stream is the drilling and recovery of hydrocarbons from strata. Often, recovery of hydrocarbon deposits is an energy and equipment intensive operation. Drill rigs are generally deployed that may drill down many thousands of feet into different strata to tap into a hydrocarbon source. In some instances, the hydrocarbon source is mixed in different phases. For example, in some instances, oil is desired to be recovered so that the recovered liquid products may be shipped by truck to a refinery. Upon drilling into the deposit, however, the deposit may have no liquid products at all, rather gaseous products (“natural gas”) is recovered. Without the technology to utilize this energy source, the gas well is closed or, if there are liquid products in the well, the gas is burned “flared” to the environment.

The flaring of gas often happens when a pipeline is not present to take these valuable products to a market source. The natural gas energy use potential, therefore, is wasted and not efficiently used.

Different types of facilities, such as computer facilities, use large amounts of energy. Siting of these computer facilities, for example, is a problem for companies that partake in these operations as the cost of electricity is a key component of operations. Often, competitors in the same industry use the same servers, racks, and personal computers. Moreover, the requirements for cooling and maintaining these electrical components are similar between competitors. One of the only costs of production for these industries that is variable is the overall cost of electricity. Currently, however, conventional computer facilities are not located in energy rich environments.

There is a need to provide apparatus and methods for more efficient production of energy and energy recovery that is easier to operate than conventional apparatus and methods.

There is a further need to provide apparatus and methods for provision of electrical power to energy intensive industries that do not have the drawbacks discussed above.

There is a still further need to reduce economic costs associated with operations and apparatus related to energy intensive industries described above with the conventional apparatus and methods.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are therefore not to be considered limiting of its scope, for the disclosure may admit to other equally effective embodiments without specific recitation. Accordingly, the following summary provides just a few aspects of the description and should not be used to limit the described embodiments to a single concept.

In one example embodiment a method is described. The method may comprise conducting a first industrial process that produces heat. The method may also comprise extracting a waste heat from the first industrial process. The method may also comprise providing the extracted waste heat from the first industrial process to a second process. The method may further comprise conducting at least one cooling process with the second process. The method may also comprise cooling a second industrial process with at least one cooling process.

In another example embodiment, a method is disclosed. The method may comprise conducting a hydrocarbon recovery operation. The method may further comprise recovering at least one of a liquid and a gaseous hydrocarbon during the hydrocarbon recovery operation. The method may further comprise burning at least one of the liquid and the gaseous hydrocarbon from the hydrocarbon recovery operation to produce a heat. The method may further comprise extracting heat from the burning of at least one of the liquid and the gaseous hydrocarbon. The method may further comprise conducting a cooling process with the heat extracted from the burning of at least one of the liquid and the gaseous hydrocarbon. The method may further comprise using the cooling process to cool at least one computer arrangement.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the drawings. It is to be noted, however, that the appended drawings illustrate only typical embodiments of this disclosure and are therefore not be considered limiting of its scope, for the disclosure may admit to other equally effective embodiments.

FIG. 1 is a drill rig performing a hydrocarbon recovery operation in one aspect of the disclosure.

FIG. 2 is a computer apparatus used in performing methods and controlling apparatus for the operations of FIG. 1.

FIG. 3 is an ammonia water refrigeration system in accordance with one example embodiment of the disclosure.

FIG. 4 is a method for energy production, use and recovery for an industrial process in accordance with one example embodiment of the disclosure.

FIG. 5 is a second method for energy production, use and recovery for an industrial process in accordance with one example embodiment of the disclosure.

To facilitate understanding, identical reference numerals have been used, where possible, to designate identical elements that are common to the figures (“FIGS”). It is contemplated that elements disclosed in one embodiment may be beneficially utilized on other embodiments without specific recitation.

### DETAILED DESCRIPTION

In the following, reference is made to embodiments of the disclosure. It should be understood, however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the claims except where explicitly recited in a claim. Likewise, reference to “the disclosure” shall not be construed as a generalization of inventive subject matter disclosed herein and shall not be considered to be an element or limitation of the claims except where explicitly recited in a claim.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. Terms such as “first”, “second” and other numerical terms, when used herein, do not imply a sequence or order unless clearly indicated by the context. Thus, a first element, component, region, layer or section discussed herein could be termed a second element, component, region, layer or section without departing from the teachings of the example embodiments.

When an element or layer is referred to as being “on.” “engaged to,” “connected to,” or “coupled to” another element or layer, it may be directly on, engaged, connected, or coupled to the other element or layer, or interleaving elements or layers may be present. In contrast, when an element is referred to as being “directly on,” “directly engaged to,” “directly connected to,” or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood, however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

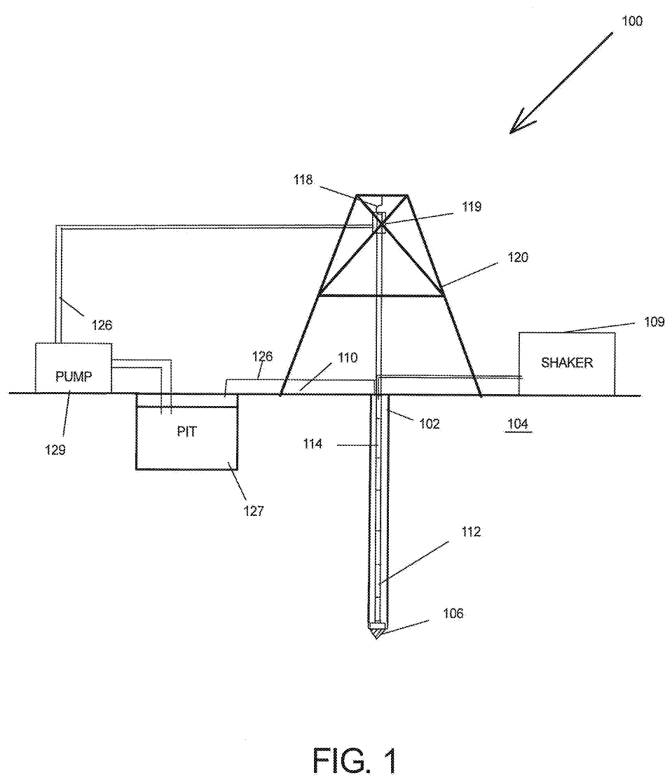

Referring to FIG. 1, a drilling rig 100 is illustrated. The purpose of the drilling rig 100 is to recover hydrocarbons located beneath the surface 110. Different stratum 104 may be encountered during the creation of a wellbore 102. In FIG. 1, a single stratum 104 layer is provided. As will be understood, multiple layers of stratum 104 may be encountered. In embodiments, the stratum 104 may be horizontal layers. In other embodiments, the stratum 104 may be vertically configured. In still further embodiments, the stratum 104 may have both horizontal and vertical layers. Stratum 104 beneath the surface 110 may be varied in composition, and may include sand, clay, silt, rock and/or combinations of these. Operators, therefore, need to assess the composition of the stratum 104 in order to achieve maximum penetration of a drill bit 106 that will be used in the drilling process. The wellbore 102 is formed within the stratum 104 by a drill bit 106. In embodiments, the drill bit 106 is rotated such that contact between the drill bit 106 and the stratum 104 causes portions (“cuttings”) of the stratum 104 to be loosened at the bottom of the wellbore 102. Differing types of drill bits 106 may be used to penetrate different types of stratum 104. The types of stratum 104 encountered, therefore, are an important characteristic for operators. The types of drill bits 106 may vary widely. In some embodiments polycrystalline diamond compact (“PDC”) drill bits may be used. In other embodiments, roller cone bits, diamond impregnated or hammer bits may be used. In embodiments, during the drilling process, vibration may be placed upon the drill bit 106 to aid in the breaking of stratum 104 that are encountered by the drill bit 106. Such vibration may increase the overall rate of penetration (“ROP”), increasing the efficiency of the drilling operations.

As the wellbore 102 penetrates further into the stratum 104, operators may add portions of drill string pipe 114 to form a drill string 112. As illustrated in FIG. 1, the drill string 112 may extend into the stratum 104 in a vertical orientation. In other embodiments, the drill string 112 and the wellbore 102 may deviate from a vertical orientation. In some embodiments, the wellbore 102 may be drilled in certain sections in a horizontal direction, parallel with the surface 110.

The drill bit 106 is larger in diameter than the drill string 112 such that when the drill bit 106 produces the hole for the wellbore 102, an annular space is created between the drill string 112 and the inside face of the wellbore 102. This annular space provides a pathway for removal of cuttings from the wellbore 102. Drilling fluids include water and specialty chemicals to aid in the formation of the wellbore 102. Other additives, such as defoamers, corrosion inhibitors, alkalinity control, bactericides, emulsifiers, wetting agents, filtration reducers, flocculants, foaming agents, lubricants, pipe-freeing agents, scale inhibitors, scavengers, surfactants, temperature stabilizers, scale inhibitors, thinners, dispersants, tracers, viscosifiers, and wetting agents may be added.

The drilling fluids may be stored in a pit 127 located at the drill site. The pit 127 may have a liner to prevent the drilling fluids from entering surface groundwater and/or contacting surface soils. In other embodiments, the drilling fluids may be stored in a tank alleviating the need for a pit 127. The pit 127 may have a recirculation line 126 that connects the pit 127 to a shaker 109 that is configured to process the drilling fluids after progressing from the downhole environment.

Drilling fluid from the pit 127 is pumped by a mud pump 129 that is connected to a swivel 119. The drill string 112 is suspended by a drive 118 from a derrick 120. In the illustrated embodiment, the drive 118 may be a unit that sits atop the drill string 112 and is known in the industry as a “top drive”. The top drive is configured to provide the rotational motion of the drill string 112 and attached drill bit 106. Although the drill string 112 is illustrated as being rotated by a top drive, other configurations are possible. A rotary drive located at or near the surface 110 may be used by operators to provide the rotational force. Power for the rotary drive or the top drive may be provided by diesel generators.

Drilling fluid is provided to the drill string 112 through a swivel 119 suspended by the derrick 120. The drilling fluid exits the drill string 112 at the drill bit 106 and has several functions in the drilling process. The drilling fluid is used to cool the drill bit 106 and remove the cuttings generated by the drill bit 106. The drilling fluid with the loosened cuttings enter the annular area outside of the drill string 112 and travel up the wellbore 102 to a shaker 109. The drilling fluid provides further information on the stratum 104 being encountered and may be tested with a viscometer, for example, to determine formation properties. Such formation properties allow engineers the ability to determine if drilling should proceed or terminate.

The shaker 109 is configured to separate the cuttings from the drilling fluid. The cuttings, after separation, may be analyzed by operators to determine if the stratum 104 currently being penetrated has hydrocarbons stored within the stratum level that is currently being penetrated by the drill bit 106. The drilling fluid is then recirculated to the pit 127 through the recirculation line 126. The shaker 109 separates the cuttings from the drilling fluid by providing an acceleration of the fluid on to a screening surface. As will be understood, the shaker 109 may provide a linear or cylindrical acceleration for the materials being processed through the shaker 109. In embodiments, the shaker 109 may be configured with one running speed. In other embodiments, the shaker 109 may be configured with multiple operating speeds. In embodiments, the shaker 109 may operate at multiple operating speeds. The shaker 109 may be configured with a low speed setting of 6.5 “g” and a high speed setting of 7.5 “g”, where “g” is defined as the acceleration of gravity. Large cuttings are trapped on the screens, while the drilling fluid passes through the screens and is captured for reuse. Tests may be taken of the drilling fluid after passing through the shaker 109 to determine if the drilling fluid is adequate to reuse. Viscometers may be used to perform such testing.

As will be understood, smaller cuttings may pass entirely through the screens of the shaker 109 such that the fluids may include many smaller size cuttings. The overall quality of the drilling fluid, therefore, may be compromised by such smaller cuttings. The drilling fluid may be, as example, water based, oil based, or synthetic based types of fluids. The fluids provide several functions, such as the capability to suspend and release cuttings in the fluid flow, the control of formation pressures (pressures downhole), maintain wellbore stability, minimize formation damage, cool, lubricate and support the bit and drilling assembly, transmission of energy to tools and the bit, control corrosion and facilitate completion of the wellbore 102. In embodiments, the drilling fluid may also minimize environmental impact of the well construction process.

The drilling, as described above, allows for the recovery of hydrocarbons in both liquid and gaseous form. The gaseous form hydrocarbons may then be utilized in future steps recited in the application. In one non-limiting embodiment, an ammonia water refrigeration unit may be used in conjunction with the gaseous hydrocarbon to enable a large heat exchange capability. This large heat exchange capability may be used in conjunction with a source that needs sufficient cooling for operation. In one embodiment, the source needing sufficient cooling may be a computer server operation. Aspects of the disclosure also provide methods that may be performed to achieve a stated goal, including controlling components described in the specification. In some embodiments, the methods described may be performed by circuits and/or computers that are configured to perform such tasks.

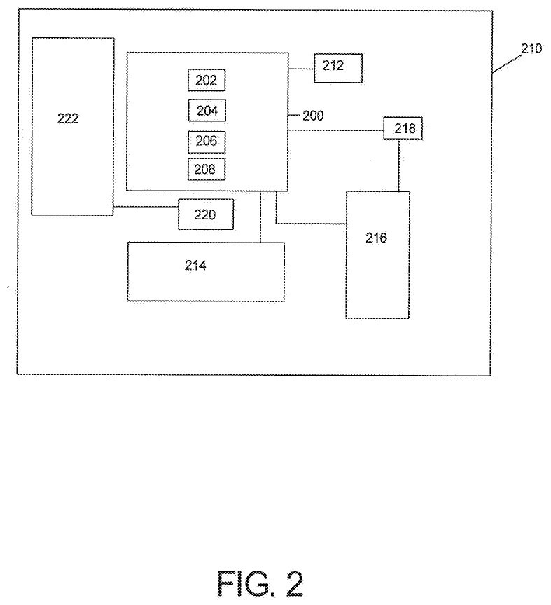

In such embodiments, referring to FIG. 2, a computing apparatus that uses the energy described above is illustrated. One embodiment of an industry that requires large amounts of power and cooling capability is a server installation where banks of computers are used to perform calculations and other required logical operations. Different components within the computing apparatus use different amounts of energy, which will be described. In FIG. 2, a processor 200 is provided to perform computational analysis for instructions provided. The instruction provided, code, may be written to achieve the desired goal and the processor may access the instructions. In other embodiments, the instructions may be provided directly to the processor 200.

In other embodiments, other components may be substituted for generalized processors. These specifically designed components, known as application specific integrated circuits (“ASIC's”) are specially designed to perform the desired task. As such, the ASIC's generally have a smaller footprint than generalized computer processors. The ASIC's, when used in embodiments of the disclosure, may use field programmable gate array technology, that allows a user to make variations in computing, as necessary. Thus, the methods described herein are not specifically held to a precise embodiment, rather alterations of the programming may be achieved through these configurations.

In embodiments, when equipped with a processor 200, the processor 200 may have an arithmetic logic unit (“ALU”) 202, a floating point unit (“FPU”) 204, registers 206 and a single or multiple layer cache 208. The arithmetic logic unit 202 may perform arithmetic functions as well as logic functions. The floating point unit 204 may be math coprocessor or numeric coprocessor to manipulate numbers more efficiently and quickly than other types of circuits. The registers 206 are configured to store data that will be used by the processor during calculations and supply operands to the arithmetic logic unit 202 and store the result of operations. The single or multiple layer caches 208 are provided as a storehouse for data to help in calculation speed by preventing the processor 200 from continually accessing random access memory (“RAM”).

Aspects of the disclosure provide for the use of a single processor 200. Other embodiments of the disclosure allow the use of more than a single processor 200. Such configurations may be called a multi-core processor where different functions are conducted by different processors to aid in calculation speed. In embodiments, when different processors are used, calculations may be performed simultaneously by different processors, a process known as parallel processing.

The processor 200 may be located on a motherboard 210. The motherboard 210 is a printed circuit board that incorporates the processor 200 as well as other components helpful in processing, such as memory modules (“DIMMS”) 212, random access memory 214, read only memory, non-volatile memory chips 216, a clock generator 218 that keeps components in synchronization, as well as connectors for connecting other components to the motherboard 210. The motherboard 210 may have different sizes according to the needs of the computer architect. To this end, the different sizes, known as form factors, may vary in size from a cellular telephone size to a desktop personal computer size. The motherboard 210 may also provide other services to aid in functioning of the processor 200, such as cooling capacity. Cooling capacity may include a thermometer 220 and temperature controlled fan 222 that conveys cooling air over the motherboard 210 to reduce temperature. The cooling capacity that is needed is determined not only by the amount of electrical load that is needed, but also by the ambient temperatures that surround the apparatus. It is therefore important to provide lower ambient temperatures to enhance computational analysis. Lower ambient temperatures reduce the thermal stress on materials and increases the overall availability of the computer services. Such lower ambient temperatures are provided by chilled air produced by air conditioning units. As will be understood, the larger number of processors, motherboards, servers and computers located within a structure, the greater the heat load that is required to be removed by the air conditioning units.

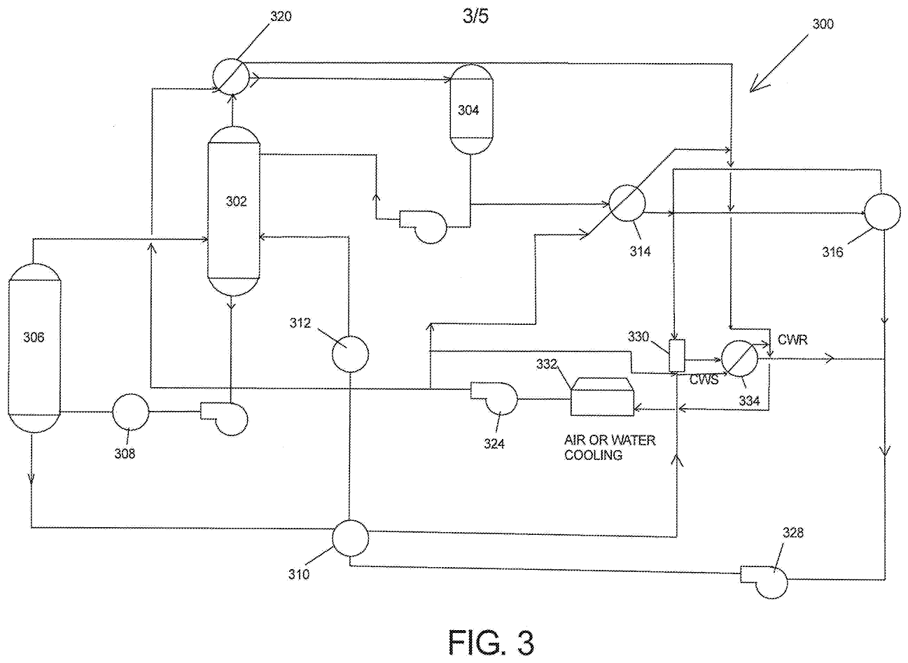

Referring to FIG. 3, a system 300 for performing a cooling using an ammonia stream is illustrated. In this ammonia water absorption refrigeration cycle, waste heat recovery may be combined with a system of absorption chilling. High temperature heat, for example from a flare system, may be used in connection with this system for refrigeration of an industrial process. This industrial process may be, as described herein, cooling of computer racks or a server farm. In FIG. 3, heat exchangers are illustrated by round elements 308, 310, 312, 314, 316, 320, and 334. A separate ammonia stream passes through heat exchanger 316 wherein an ammonia vapor is provided to the heat exchanger 316 and after processing, the ammonia is condensed into a liquid for later pumping and reheating in a further refrigeration portion. Waste heat from the system 300 may be pumped through an air cooler, or a cooling tower 332 from a cooling water supply that condenses and is pumped by pump 324 passing to a further heat exchanger 320 that again recirculates back to the cooling tower 332. At heat exchanger 312, a provision is provided to heat a water stream that passes. The heat transfers from heat exchanger 312 to the fluid stream that passes to receiver 302 for hot water. Additional water that is heated may exit receiver 306 entering the receiver 302. Condensed water from the receiver 302 drains from the receiver 302 and may enter an additional heat exchanger 308 used for spent water. The stream entering receiver 306 is thus cooled and liquid components pass to heat exchanger 310. This water stream may be heated through heat exchanger 310 that accepts water from pump 328 which is, in turn, connected to the ammonia system heat exchanger 316. The water from pump 328 is heated through heat exchanger 310 as well at the water jacket heat exchanger 312, completing this cycle. Water entering the heat exchanger 310 from the receiver 306 may pass to a mixer 330 passing to a heat exchanger 334 that has a cooling water supply and cooling water return. Water from the heat exchanger 316 connected to the ammonia system may enter the mixer and then pass through the heat exchanger 334 to the pump 328 for further recirculation back to heat exchanger 310. At pump 324, the water may be split between heat exchanger 320 and a take off that extends partially up to heat exchanger 314 and eventually draining back to the cooler 332. Another part of the water pumped from pump 324 is recirculated back through the heat exchanger 324. Water that has condensed from receiver 304 may be spit and pumped by pump 326 to receiver 302, or may be processed through heat exchanger 314, eventually processing to heat exchanger 316 for conducting heat exchanging with the ammonia system at heat exchanger 316. Receiver 304 is used to condense water provided to it by heat exchanger 320 which is then pumped as described above. As will be understood, systems and components provided above may be used in conjunction with heat recovery systems to provide an efficiency previously not attained by such systems.

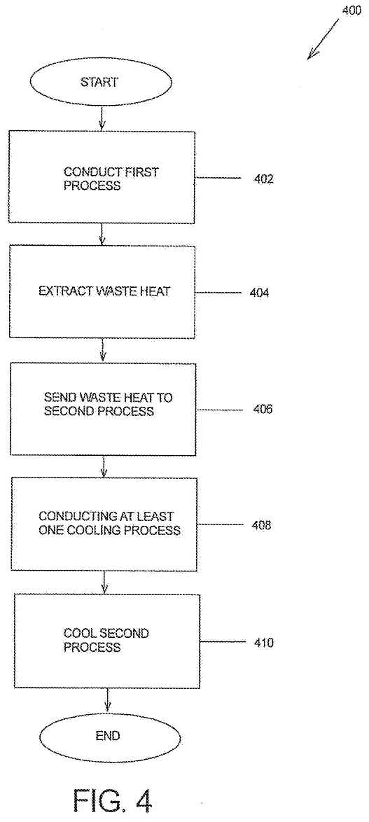

Referring to FIG. 4, a method 400 is described. The method may comprise, at 402, conducting a first industrial process that produces heat. At 404, the method may comprise extracting a waste heat from the first industrial process. At 406, the method may comprise providing the extracted waste heat from the first industrial process to a second process. At 408, the method may comprise conducting at least one cooling process with the second process. At 410, the method may comprise cooling a second industrial process with at least one cooling process. As will be understood, in one non-limiting embodiment, generation of electricity may be performed after the conducting of the first industrial process. This generation of electricity may be done through running combustion gasses or other gasses through, for example, a turbine to produce electricity. Embodiments of the disclosure may also provide for heating of building systems with the waste heat, in the event of a cold climate. Waste heat may be used from the flaring system or the systems using heat exchangers may reverse their respective process lines, or add feedback loops and/or components to allow heat to be delivered to an area, as needed. In embodiments where hydrogen sulfide may be used as a combustion gas, precautions may be made such that discharges from the combustion process are not harmful to the environment.

In the embodiments described above, the first industrial process may be, for example, a hydrocarbon recovery operation where oil and/or gas is being recovered by a rig. The rig may be located on land or sea. The waste heat may be, for example, from flaring gaseous products generated from the wellbore. Such gaseous products may be methane, hydrogen sulfide or other gases. The second process may be running a computer server farm, as a non-limiting embodiment, wherein the cooling process cools the computers to a temperature that is needed for proper operation.

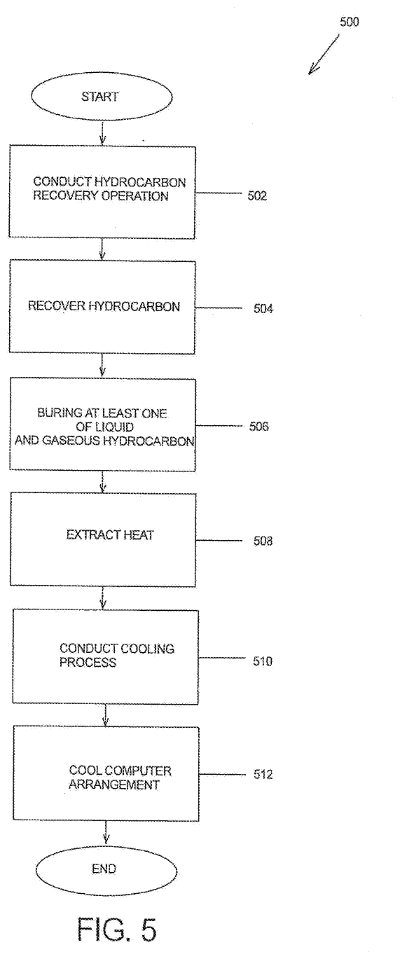

Referring to FIG. 5, a method 500 is described. The method may comprise, at 502, conducting a hydrocarbon recovery operation. The method continues, at 504, by recovering at least one of a liquid and a gaseous hydrocarbon during the hydrocarbon recovery operation. At 506, the method continues by burning at least one of the liquid and the gaseous hydrocarbon from the hydrocarbon recovery operation to produce a heat. At 508, the method continues by extracting heat from the burning of at least one of the liquid and the gaseous hydrocarbon. At 510, the method continues by conducting a cooling process with the heat extracted from the burning of at least one of the liquid and the gaseous hydrocarbon. At 512 the method continues by using the cooling process to cool at least one computer arrangement.

As will be understood, a heat source will be generated to provide for cooling purposes. In normal or conventional applications the flaring of gas is considered a necessary operation to prevent for the unmitigated release of methane gas from a wellbore. The energy of the flare gas is lost in such a configuration. In embodiments herein, however, the energy developed may be used to provide a source of energy for a refrigeration system. In the illustrated embodiments, an ammonia water refrigeration system, such as that in FIG. 3, is used. Other embodiments may use different types of refrigeration systems and therefore the ammonia water refrigeration system should not be considered limiting. In some embodiments, the flare may additionally be used to produce electricity that may be used to power motors within the refrigeration system. In other embodiments, where the amount of hydrocarbon gas is large, electricity made from the gas may be used to power components, such as the end use operation of a server farm, as a non-limiting embodiment. Production of electrical energy may be performed through heating of air and channeling of the heated air to a turbine. As will be further understood, many gas wells may be combined together into a single gas turbine, thereby allowing for greater possible electrical production.

In one example embodiment, a method is disclosed. The method may comprise conducting a first industrial process that produces heat. The method may also comprise extracting a waste heat from the first industrial process. The method may also comprise providing the extracted waste heat from the first industrial process to a second process. The method may also comprise conducting at least one cooling process with the second process. The method may also comprise cooling a second industrial process with at least one cooling process.

In other embodiments, the methods described may be connected with other generation technologies to increase efficiency. In some embodiments, sour gas (“hydrogen sulfide”) is flared to eliminate the potentially hazardous gas from a wellbore. By flaring this gas and collecting the energy for usage, the amount of energy efficiency is increased for the entire operation where energy previously wasted is beneficially used. In the hydrocarbon recovery operations, such as vertical and/or horizontal drilling, different wellbores may be merged into a single wellhead, minimizing the amount or flaring systems used to recover energy previously wasted.

In another example embodiment, the method may be performed wherein the first industrial process is a hydrocarbon recovery operation.

In another example embodiment, the method may be performed wherein the hydrocarbon recovery operation is a drilling operation.

In another example embodiment, the method may be performed wherein the extracting of the waste heat includes a flaring of a hydrocarbon gas.

In another example embodiment, the method may be performed wherein the flaring of the hydrocarbon gas is a methane gas.

In another example embodiment, the method may be performed wherein the second industrial process is a cooling process for at least one of a computer, server, and electrical component.

In another example embodiment, the method may be performed wherein the second process is a heat exchanging system.

In another example embodiment, the method may be performed wherein the second process uses ammonia.

In another example embodiment, the method may be performed wherein the second process also uses water.

In another example embodiment, a method may be performed including steps of conducting a hydrocarbon recovery operation and recovering at least one of a liquid and a gaseous hydrocarbon during the hydrocarbon recovery operation. The method may further be performed by burning at least one of the liquid and the gaseous hydrocarbon from the hydrocarbon recovery operation to produce a heat. The method may also include extracting heat from the burning of at least one of the liquid and the gaseous hydrocarbon. The method may also include conducting a cooling process with the heat extracted from the burning of at least one of the liquid and the gaseous hydrocarbon. The method may also include using the cooling process to cool at least one computer arrangement.

In another example embodiment, the method may be performed wherein at least one computer arrangement is a server farm.

In another example embodiment, the method may be performed wherein the burning includes burning of at least one methane source.

In another example embodiment, the method may be performed wherein the burning includes burning of at least one hydrogen sulfide source.

In another example embodiment, the method may be performed wherein the cooling process uses ammonia.

In another example embodiment, the method may be performed wherein the cooling process additionally uses water.

In another example embodiment, the method may be performed wherein the hydrocarbon recovery operation is a drilling operation.

In another example embodiment, the method may be performed wherein the conducting of the cooling process includes operation of at least one of a heat exchanger and a chiller.

In another example embodiment, the method may be performed wherein the cooling process includes at least one condenser.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may be varied in many ways. Such variations are not to be regarded as a departure from the disclosure, and all such modifications are intended to be included within the scope of the disclosure.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

1. A method, comprising:
conducting a first industrial process that produces heat, wherein the first industrial process is a thermal power generation;
extracting a waste heat from the heat produced from a system from the first industrial process;
providing the extracted waste heat from the heat produced from the first industrial process to a second process;
conducting at least one cooling process with the second process, and wherein the cooling process involves both a mechanical refrigeration process and an ammonia water absorption refrigeration cycle; and
cooling a second industrial process with the at least one cooling process wherein the second industrial process is performing computer operations for a server farm.

2. The method of claim 1, wherein the first industrial process is at least one of a hydrocarbon recovery operation and a power generation.

3. The method of claim 2, wherein the hydrocarbon recovery operation is a drilling operation.

4. The method of claim 2, wherein the extracting the waste heat includes a burning of a hydrocarbon gas.

5. The method of claim 4, wherein the burning of the hydrocarbon gas is a methane gas.

6. (canceled)

7. (canceled)

8. (canceled)

9. (canceled)

10. A method, comprising:
conducting a hydrocarbon recovery operation;
recovering at least one of a liquid and a gaseous hydrocarbon during the hydrocarbon recovery operation;
burning at least one of the liquid and the gaseous hydrocarbon from the hydrocarbon recovery operation to produce heat;
extracting waste heat from a system that conducts the burning of the at least one of the liquid and the gaseous hydrocarbon; and
conducting a cooling process wherein the cooling process is both a mechanical refrigeration process and an ammonia water absorption refrigeration cycle for a server farm with the heat extracted from the burning of the at least one of the liquid and the gaseous hydrocarbon.

11. (canceled)

12. The method according to claim 10, wherein the burning includes burning of at least one methane source.

13. The method according to claim 10, wherein the burning includes burning of at least one hydrogen sulfide source.

14. (canceled)

15. (canceled)

16. The method according to claim 10, wherein the hydrocarbon recovery operation is a drilling operation.

17. The method according to claim 10, wherein the conducting the cooling process includes operation of at least one of a heat exchanger and a chiller.

18. The method according to claim 17, wherein the cooling process includes at least one condenser.
